(19) United States
(12) Patent Application Publication
(10) Pub. No.: US 2022/0134386 A1
(43) Pub. Date: May 5, 2022

(54) CLEANING MEMBER, AND METHOD FOR MANUFACTURING THE SAME

(71) Applicant: Kao Corporation, Tokyo (JP)

(72) Inventors: Takehiko TOJO, Utsunomiya-shi (JP); Takehiko UEMATSU, Oyama-shi (JP); Masahiko SUZUKI, Sennan-shi (JP)

(73) Assignee: Kao Corporation, Tokyo (JP)

(21) Appl. No.: 17/433,843

(22) PCT Filed: Feb. 25, 2020
(86) PCT No.: PCT/JP2020/007541

§ 371 Date: Aug. 25, 2021

(30) Foreign Application Priority Data
Feb. 28, 2019 (JP) 2019-037024

(51) Int. Cl. B08B 1/00; D01D 5/04; D04H 1/4382; D04H 1/728

(52) U.S. Cl. CPC B08B 1/001; D01D 5/04; D10B 2505/00; D04H 1/728; D10B 2401/10; D04H 1/4382

(57) ABSTRACT

A cleaning member includes a nonwoven structure whose shape is retained by entanglement between single fibers having a median fiber diameter of from 100 to 2000 nm. The nonwoven structure has an apparent density of from 0.05 to 0.60 g/cm³. Preferably, the cleaning member may further include a support, and the support and the nonwoven structure may be arranged in contact with one another. Preferably, the single fiber may be an electrospun fiber. A method for manufacturing a cleaning member includes: a step of performing spinning by electrospinning, and thereby forming a deposit of a single fiber; and a step of pressing the deposit, and thereby forming a nonwoven structure having an apparent density of from 0.05 to 0.60 g/cm³.

### TECHNICAL FIELD

The present invention relates to a cleaning member, and a method for manufacturing the same.

### BACKGROUND ART

In recent years, ultrafine fibers with diameters of less than several micrometers are being used for various applications in the form of fiber aggregates obtained by entangling the fibers. For example, Patent Literature 1 discloses a cleaning process fabric consisting of a nonwoven fabric formed by entanglement between ultrafine fibers and/or ultrafine fiber strands, wherein the number-average diameter of single fibers is from 1 to 400 nm, and the weight percentage of single fibers having diameters from 1 to 400 nm is 60% or greater within all the ultrafine fibers. The Patent Literature describes that the cleaning process fabric has a closely packed structure and can be used for cleaning substrates for magnetic recording media.

### CITATION LIST

### Patent Literature

Patent Literature 1: JP 2008-55411A

### SUMMARY OF INVENTION

The present invention relates to a cleaning member.

In one embodiment, the cleaning member includes a nonwoven structure whose shape is retained by entanglement between single fibers having a median fiber diameter of from 100 to 2000 nm.

In one embodiment, the nonwoven structure having an apparent density of from 0.05 to 0.60 g/cm³.

The present invention also relates to a method for manufacturing the aforementioned cleaning member.

In one embodiment, the manufacturing method includes a step of discharging a solution or a melt of an electrospinning composition into an electric field and spinning the solution or the melt by electrospinning, and thereby forming a deposit of a single fiber.

In one embodiment, the manufacturing method includes a step of pressing the deposit, and thereby forming a nonwoven structure having a density of from 0.05 g/cm³ to 0.60 g/cm³.

### BRIEF DESCRIPTION OF DRAWINGS

FIG. 1(a) is a schematic diagram illustrating an entangled state of a single fiber included in a nonwoven structure of a cleaning member according to the present invention, and FIG. 1(b) is a schematic diagram illustrating an arrangement of fibers present on the surface of a fiber sheet according to conventional art.

FIG. 2 is a schematic diagram illustrating an embodiment of a cleaning member according to the present invention.

FIGS. 3(a) to 3(d) are schematic diagrams illustrating other embodiments of cleaning members according to the present invention.

FIG. 4 is a schematic diagram illustrating a method for manufacturing a single fiber using a manufacturing device.

FIGS. 5(a) and 5(b) respectively illustrate images and a graph showing particulate removal performance when cleaning members according to a working example and a comparative example were used for cleaning.

### DESCRIPTION OF EMBODIMENTS

The cleaning process fabric disclosed in Patent Literature 1 employs its closely packed and highly dense structure to scrape out and remove particulates, such as abrasive grains and grinding dust, remaining on a surface being cleaned.

The cleaning process fabric disclosed in the Patent Literature, however, is inadequate in terms of scraping out and removing particulates. There is a demand for improvement in particulate cleaning efficiency.

The present invention relates to a cleaning member having an improved capability for cleaning/removing particulates adhering to a surface to be cleaned, and a method for manufacturing the same.

The present invention will be described below according to preferred embodiments thereof with reference to the drawings. The present invention relates to a cleaning member.

Herein, “cleaning” encompasses cleansing/scavenging and wiping of an object. For example, “cleaning” may encompass cleaning of building parts such as the floor, wall surfaces, ceiling, pillars, etc., cleansing of fittings and equipment, wiping of various articles, wiping of the body and instruments related to the body.

The cleaning member of the present invention is suitably used particularly for cleaning surfaces of precision electronic components—e.g., semiconductor substrates, such as silicon wafers or semiconductor wafers, and magnetic recording substrates—that require smoothness of the surface being cleaned.

The cleaning member of the present invention includes a nonwoven structure constituted by an aggregate of single fibers. The shape of the nonwoven structure is retained by entanglement between the single fibers.

The nonwoven structure is a deposit formed by depositing the single fibers randomly and entangling the single fibers. The nonwoven structure may further be subjected to a shape retention process such as pressing, as necessary. Among the single fibers, voids where there are no single fibers are present three-dimensionally so as to penetrate the sheet's planar direction and thickness direction. The voids are in communication with one another, to form fine holes (also referred to as “pores” hereinafter) inside the nonwoven structure. These holes typically form open pores which are in communication with one another.

The single fibers included in the nonwoven structure may have sections where they contact one another, but are not bonded together by fusion etc. In cases where there are contact points where the single fibers contact one another, the single fibers are not bonded together, but it is preferable that the cross-sectional shape of at least one of the single fibers at the contact point between the single fibers is deformed into a shape that is different from the cross-sectional shape of the single fiber at a non-contact point. Herein, “single fiber” refers to an individual fiber that does not form a fiber strand, and is intended to exclude fibers constituted by fiber strands.

The median fiber diameter of the single fiber is preferably 100 nm or greater, more preferably 200 nm or greater, even more preferably 250 nm or greater, and preferably 2000 nm or less, more preferably 1000 nm or less, even more preferably 900 nm or less.

Using a single fiber having such a fiber diameter enables efficient removal of particulates, with particle sizes of 100 nm or less, adhering to a surface being cleaned.

The “fiber diameter” can be measured as follows. For example, an observation surface of the nonwoven structure is observed with a scanning electron microscope (SEM), and from the obtained two-dimensional image, 500 pieces of fibers are selected arbitrarily, excluding fiber clusters and intersecting sections between fibers. The diameter of each fiber is defined as the length between the two intersection points between a straight line orthogonal to the fiber's longitudinal direction and the fiber's contour. The median of measured fiber diameters is considered the median fiber diameter.

The nonwoven structure may include fibers having a fiber diameter below 100 nm or above 2000 nm, so long as the effects of the present invention are not lost, but it is preferable that the nonwoven structure contains only single fibers having a fiber diameter of from 100 nm to 2000 nm.

The thickness of the nonwoven structure is preferably 0.02 mm or greater, more preferably 0.04 mm or greater, even more preferably 0.06 mm or greater, and preferably 30 mm or less, more preferably 25 mm or less, even more preferably 20 mm or less.

Having such a thickness is excellent for removing particulates adhering to an object being cleaned, while maintaining the strength of the cleaning member.

The nonwoven structure having a thickness within the aforementioned range may have, for example, a sheet-like shape, or a bulk-like shape, such as a plate-like shape, a prism-like shape, a cylindrical shape, a block-like shape, or the like.

The thickness of the nonwoven structure can be adjusted as appropriate by, for example, the content of single fibers or compression at the time of shaping. The thickness of the nonwoven structure can be measured, for example, using a scanning electron microscope by observing a cross section of the nonwoven structure to be measured, as will be described below.

Herein, “sheet-like” means that the thickness of the nonwoven structure is from 10 μm to 1000 μm.

“Bulk-like” refers to a shape having a size whose contour can be recognized with the naked eye, and refers, for example, to a shape having a thickness exceeding 1 mm, wherein “thickness” is defined as the length of the shortest dimension of the three dimensions, i.e., the length, width and depth, of the nonwoven structure. Herein, “thickness” refers to the thickness of the nonwoven structure measured according to the below-described measurement method under no load.

Regardless of the shape of the nonwoven structure, the apparent density thereof is preferably 0.05 g/cm³ or greater, more preferably 0.10 g/cm³ or greater, even more preferably 0.20 g/cm³ or greater, and preferably 0.60 g/cm³ or less, more preferably 0.55 g/cm³ or less, even more preferably 0.50 g/cm³ or less.

Such a density enables the single fibers to easily scrape off particulates adhering to a surface being cleaned. Also, many voids can be provided among the single fibers, which can improve the nonwoven structure's retainability of particulates being removed. As a result, particulates adhering to an object being cleaned can be removed efficiently.

A nonwoven structure having such an apparent density can be manufactured, for example, according to a method described further below.

The apparent density of the nonwoven structure can be measured according to the following method. Specifically, the nonwoven structure is cut with a single-edge razor blade (product number FAS-10) from Feather Safety Razor Co., Ltd., to form a cross section of the nonwoven structure. Then, the cut cross section is magnified and observed with a scanning electron microscope (model number JCM-5100) from JEOL Ltd. The cross section observed under magnification is obtained as image data or is printed, to measure the thickness of the nonwoven structure under no load. Fiber fuzz that inevitably exists on the surface of the nonwoven structure is excluded from the measurement. The thickness of the nonwoven structure is the average value of the thickness in the image observed under magnification according to the aforementioned method. Then, the nonwoven structure is cut to obtain a piece having a predetermined area (e.g., 4×4 cm), and the basis weight is calculated from its mass and area. Then, the basis weight is divided by the thickness, to calculate the apparent density.

According to the cleaning member having the aforementioned configuration, the single-fiber-containing nonwoven structure includes constituent fibers with fine diameters and also has minute voids between the fibers, the voids being in communication with one another to form a multitude of open pores, and thus, the nonwoven structure has low apparent density. With this configuration, particulates present on a surface being cleaned can be scraped off by the single fibers, and therefore particulates adhering to the surface being cleaned can be collected and removed efficiently. Further, the particulates can be retained in the voids between the fibers, thereby preventing recontamination of the surface being cleaned. This results in excellent capability for cleaning particulates from the surface being cleaned. Further, using the cleaning member of the present invention for cleaning an object like a semiconductor substrate—e.g., a semiconductor wafer such as a silicon wafer—can effectively remove particulates having a particle size of 100 nm or less, such as abrasive grains or grinding dust remaining on the surface being cleaned. This can thus reduce the frequency of occurrence of surface defects caused by remaining particulates.

Particularly, using the cleaning member with a cleaning liquid, such as a polishing liquid, allows particulates produced by polishing to be adsorbed toward the cleaning member together with the cleaning liquid, thus further improving the capability of cleaning and removing particulates.

From the viewpoint of making the aforementioned effects even more notable, it is preferable that the nonwoven structure constituting the cleaning member has a porosity within a specific range. “Porosity (%)” is a value calculated according to the following equation (1). In cases where there are a plurality of materials for the single fibers, the density calculated from the densities of the respective materials and the ratio between the materials' mass contents is employed as the density of the materials of the single fibers.

Porosity(%)=100×((Density of material of single fibers[g/cm³])−(Apparent density of nonwoven structure [g/cm³]))/(Density of material of single fibers [g/cm³]) (1).

The porosity of the nonwoven structure of the present invention is preferably 30% or greater, more preferably 40% or greater, even more preferably 50% or greater, and preferably 75% or less, more preferably 70% or less, even more preferably 65% or less.

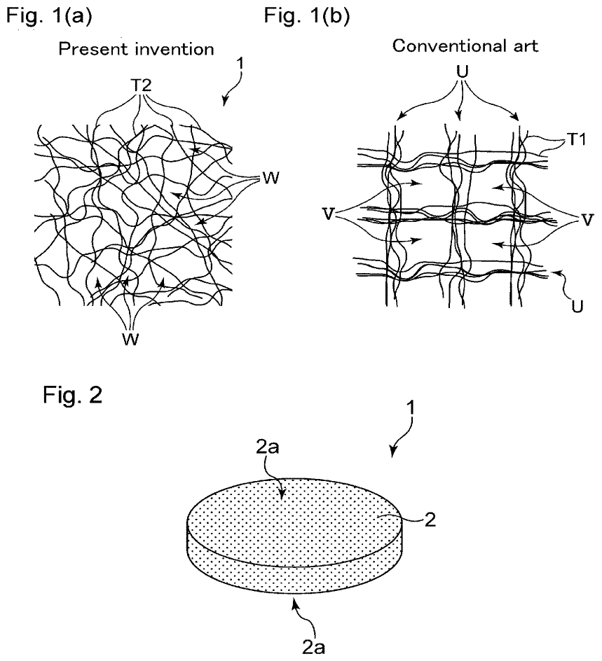

As illustrated in FIG. 1(a), in the cleaning member of the present invention, a multitude of single fibers T2 are entangled in a nonwoven state wherein the fibers are oriented randomly, and therefore, the fiber-to-fiber distances vary from short to long. Thus, the voids W formed between the fibers also have random sizes. As a result, when the void distribution of the cleaning member of the present invention is measured in terms of pore volume distribution, a high peak is observed within a range where the pore size is small.

More specifically, it is preferable that the nonwoven structure not only has a porosity within the aforementioned preferred range, but in a pore volume distribution, the nonwoven structure has a distribution including a top peak within a pore size range of 50 μm or less and including no top peak within a pore size range of above 50 μm. Herein, “including no top peak within a pore size range of above 50 μm” means that, with reference to the height of the highest peak—i.e., the top peak—within a pore size range of 50 μm or less, there is no peak having a height greater than half the height of the highest peak within a pore size range of above 50 μm.

In contrast, as illustrated in FIG. 1(b), in a fiber sheet according to conventional art—i.e., in a fiber sheet, or woven fabric or knitted fabric, which employs fiber strands or is manufactured so as to form fiber strands—fibers T1 constituting the sheet are present according to a given orientation. The fiber sheet according to conventional art as illustrated in FIG. 1(b) includes two types of regions: closely packed fiber regions U wherein the fiber-to-fiber distance is relatively short and the voids are small; and separated fiber regions V wherein the fiber-to-fiber distance is relatively long and the voids are large. When the void distribution of such a fiber sheet is measured, two peaks are observed: a peak attributable to the closely packed fiber regions having small voids; and a peak attributable to the separated fiber regions having large voids.

The distribution of voids (pores) in the nonwoven structure can be measured in terms of pore volume distribution according to the following method according to, for example, mercury porosimetry prescribed in JIS R 1655.

More specifically, a measurement sample weighing from 0.02 g to 0.1 g is cut out from an object to be measured. A measurement cell containing the measurement sample is set to a mercury porosimeter (AutoPore IV9500 from Micromeritics), to measure the cumulative pore volume V1 (mL/g) of the measurement sample when the mercury intrusion pressure P is increased within a predetermined range. Then, a pore volume distribution is obtained by plotting, on the horizontal axis, the converted pore size (diameter) D (μm) converted according to the following equation (2), and plotting the logarithmic differential pore volume (d(V1)/d(log₁₀ D); mL/g) on the vertical axis. That is, a pore volume distribution is obtained by plotting the converted pore size D on the horizontal axis and plotting the pore volume found by differentiating the cumulative pore volume V1 with respect to the logarithm of the pore size (diameter) D on the vertical axis.

D=4γ cos θ/P (2).

(γ: Surface tension of mercury; θ: contact angle; P: mercury intrusion pressure.)

The aforementioned measurement is performed in an environment of 22° C. and 65% RH. The surface tension γ of mercury is 480 dyn/cm, the contact angle θ is 140°, and the mercury intrusion pressure P is within the range from 0 psia (0 MPa) to 60000 psia (413.685 MPa). Based on a distribution curve of the converted pore size D obtained according to the aforementioned measurement conditions, the cumulative total of the converted pore sizes D within the range from 0.0018 μm to 100 μm is considered the cumulative pore volume V1 (mL/g), and the median of the pore size in the distribution curve is considered the pore size D₀ (μm) in the present invention. It is preferable that, in the aforementioned pore volume distribution wherein the cumulative pore volume is differentiated with respect to the logarithm of the pore size, the nonwoven structure of the present invention has a distribution including a top peak within a pore size range of 50 μm or less and including no top peak within a pore size range of above 50 μm.

From the same viewpoint, it is preferable that the nonwoven structure's pore size D₀, as the pore diameter, is preferably 10 nm or greater, more preferably 50 nm or greater, and preferably 50 μm or less, more preferably 30 μm or less.

From the same viewpoint, it is preferable that the nonwoven structure's cumulative pore volume V1 is preferably 0.8 mL/g or greater, more preferably 1.0 mL/g or greater, and preferably 20 mL/g or less, more preferably 10 mL/g or less. A nonwoven structure having the aforementioned void distribution, pore size and pore volume can be manufactured, for example, according to the method described below.

In the cleaning member of the present invention, the shape of the nonwoven structure included in the cleaning member may be changed depending on the configuration or use of the object being cleaned, or the nonwoven structure may be employed in combination with another member.

More specifically, as illustrated in FIG. 2, the cleaning member 1 may be configured to include a nonwoven structure 2 constituted by a molded product obtained by compression-molding a deposit formed by entanglement between the single fibers. The cleaning member 1 illustrated in the figure is constituted by a nonwoven structure 2 which is a bulk-like compression-molded product and has a plate-like shape having two opposing principal surfaces 2a and 2a. The cleaning member 1 can be used as-is for cleaning an object being cleaned, or can be used by impregnating the nonwoven structure with water or a cleaning liquid etc. Stated differently, in the configuration illustrated in the figure, the shape of the cleaning member 1 is substantially identical to the shape of the nonwoven structure 2. In the configuration illustrated in the figure, the effects of the present invention can be attained regardless of which surface of the cleaning member 1 is used as the cleaning surface (i.e., the surface facing the surface being cleaned); however, from the viewpoint of improving cleaning efficiency, it is preferable that the cleaning surface is the surface having a large contact area with the surface being cleaned—i.e., the principal surface 2a.

Further, the cleaning member may further include, in addition to the nonwoven structure, a support such as a sponge, a cleaning pad or a roller, and the support and the nonwoven structure may be arranged in contact with one another.

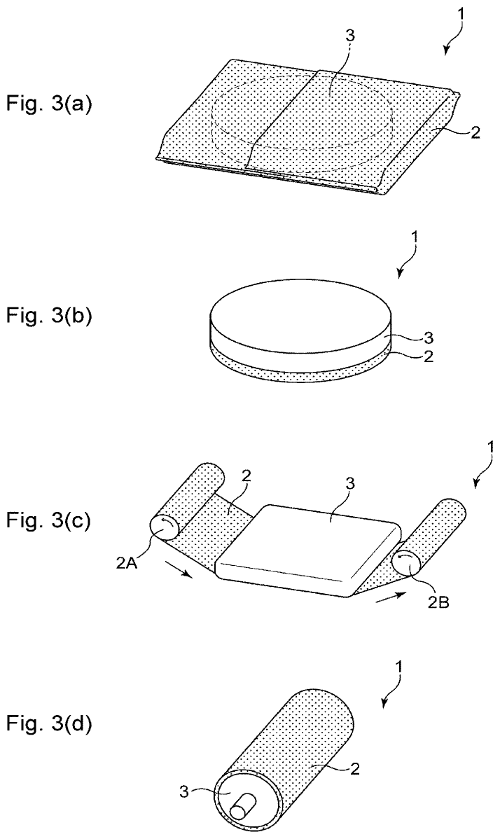

More specifically, as illustrated in FIG. 3(a), a sheet-like nonwoven structure 2 may be arranged so as to cover the entire surface of a plate-like support 3. Alternatively, as illustrated in FIG. 3(b), a laminate may be formed, wherein a nonwoven structure 2 having, for example, a sheet-like shape or a bulk-like shape such as a plate-like shape, is arranged on at least one surface of a plate-like support 3.

Alternatively, it is possible to adopt a configuration including a first roll 2A from which a sheet-like nonwoven structure 2 is paid out, a second roll 2B for taking up the paid-out nonwoven structure 2, and a support 3 to be arranged on the upper surface of the sheet-like nonwoven structure 2 that has been paid out—i.e., a configuration wherein a sheet-like nonwoven structure 2 being transported in one direction according to a roll-to-roll method is provided on one surface side of a support 3, as illustrated in FIG. 3(c).

Alternatively, it is possible to adopt a configuration wherein a sheet-like nonwoven structure 2 is arranged on the circumferential surface of a roller-shaped support 3, as illustrated in FIG. 3(d). In the configurations illustrated in FIGS. 3(a) to 3(d), the surface on the side where the nonwoven structure 2 is provided is used as the cleaning surface of the cleaning member 1, to thereby offer excellent capability of removing particulates present on a surface to be cleaned.

Particularly, the configurations illustrated in FIGS. 3(b) to 3(d) are advantageous in terms that an existing support—regardless of the support's shape or material—can be easily modified and used in a manner that the efficiency for cleaning/removing particulates is improved. From the viewpoint of preventing unintended creation of defects such as scratches on the surface being cleaned, it is preferable that the support 3 includes polyurethane, polyvinyl acetal, elastomer resin, or the like.

In cases of shaping the nonwoven structure into a sheet-like shape, the basis weight of the nonwoven structure can be selected as appropriate depending on the concrete use of the nonwoven structure.

Next, features that are applicable in common to the aforementioned embodiments will be described. In cases where the nonwoven structure of the cleaning member has a sheet-like shape, it is preferable that the water droplet permeation time is within a specific range. More specifically, it is preferable that the permeation time required for a water droplet to permeate into the sheet-like nonwoven structure is preferably 1 minute or less, more preferably 40 seconds or less, even more preferably 20 seconds or less.

With such water absorbency, particulate-cleaning capability can be further improved. Particularly, when the cleaning member is used together with a cleaning liquid, the retainability of the cleaning liquid can be improved, and as a result, particulate removal efficiency can be further improved. A shorter permeation time required for a water droplet to permeate into the sheet-like nonwoven structure means higher hydrophilicity of the single fibers.

“Hydrophilicity of fibers” means high retainability of water or aqueous liquid between the fibers.

The permeation time of a water droplet to permeate into the sheet-like nonwoven structure can be measured, for example, according to the following method. Two pairs of stainless-steel (SUS) plates, with a thickness of 10 mm, are used to respectively sandwich and hold both ends of the sheet-like nonwoven structure. In this state, tension is applied to the nonwoven structure, and the nonwoven structure is fixed in a manner separated from a test stage. Then, 15 μL of a droplet of ion-exchanged water is dropped from above onto the fixed nonwoven structure with tension applied thereto. The surface on which the water droplet has been dropped is observed with the eyes, and the time from when the water droplet was dropped until the water droplet becomes completely invisible is considered the water droplet permeation time. The size of the nonwoven structure being measured is 80 mm×50 mm. The distance between the pairs of stainless-steel plates is set to 50 mm. The nonwoven structure is sandwiched by the plates with tension applied thereto such that the sample does not slacken, and the water droplet is dropped onto the center position from above from a height of 10 mm.

The method for manufacturing the single fibers constituting the nonwoven structure is not particularly limited, so long as the fiber thickness is within the aforementioned range. For example, fibers manufactured by melt-blowing or electrospinning can be used. Particularly, it is preferable that the single fibers used in the present invention are electrospun fibers.

By using such fibers, it is possible to easily manufacture a nonwoven structure containing small-diameter fibers at a predetermined density. Electrospinning is a method wherein a solution or a melt containing a resin, serving as a fiber material, is discharged into an electric field while being applied with high voltage, which thereby causes the discharged solution or melt to be thinly drawn and elongated, thus forming fine fibers having a long fiber length and small fiber diameter.

For the material of the single fiber, it is preferable to use a thermoplastic resin having fiber formability. Examples of such thermoplastic resin may include: polyolefin resins, such as polyethylene, polypropylene, ethylene-α-olefin copolymer, and ethylene-propylene copolymer; polyester resins, such as polyethylene terephthalate; polyamide resins, such as polyamide 6 and polyamide 66; vinyl resins, such as polyvinyl chloride and polystyrene; and acrylic resins, such as polyacrylate and polymethyl methacrylate. One type of resin may be used singly, or two or more types may be used in combination.

The content of the thermoplastic resin used as a material resin, with respect to 100 parts by mass of all constituent components of the single fiber, is preferably 70 parts by mass or greater, more preferably 75 parts by mass or greater, even more preferably 80 parts by mass or greater, and preferably 98 parts by mass or less, more preferably 97 parts by mass or less, even more preferably 90 parts by mass or less.

In cases of electrospinning a solution of resin, examples of usable dispersion solvents for dispersing the resin may include: aprotic polar solvents, such as dimethylsulfoxide, dimethylacetamide, dimethylformamide and N-methylpyrrolidone; alcohols, such as glycerin, ethylene glycol and ethanol; ketones, such as acetone and methylethyl ketone; halogen-based solvents, such as dichloromethane and chloroform; and inorganic salt-based solvents, such as nitric acid, zinc chloride aqueous solutions and sodium thiocyanate aqueous solutions. One type of solvent may be used singly, or two or more types of solvents may be used as a mixture.

The single fibers constituting the nonwoven structure preferably contain an ionic surfactant. By including an ionic surfactant in the single fibers, it is possible to easily manufacture a nonwoven structure containing small-diameter fibers at a predetermined density.

In addition, in cases of forming the single fibers by electrospinning, the amount of electric charge in the material resin can be increased, and thus, a solution or a melt containing the resin can be drawn efficiently. As a result, fibers with even smaller diameters can be manufactured with high production efficiency. Moreover, the produced fibers can easily be rendered hydrophilic.

The content of the ionic surfactant, with respect to 100 parts by mass of all constituent components of the single fiber, is preferably 2 parts by mass or greater, more preferably 4 parts by mass or greater, even more preferably 5 parts by mass or greater, and preferably 10 parts by mass or less, more preferably 8 parts by mass or less, even more preferably 6 parts by mass or less.

Ionic surfactants may be cationic surfactants, zwitterionic surfactants, or anionic surfactants. Among these ionic surfactants, one type may be used singly. Alternatively, two or more types of ionic surfactants may be used in combination, so long as they have the same ionicity. For example, for the ionic surfactants, a plurality of cationic surfactants may be used, or a plurality of zwitterionic surfactants may be used, or a plurality of anionic surfactants may be used.

Examples of cationic surfactants may include: amine salt-type cationic surfactants, such as fatty acid ester amine salts, fatty acid amide amine salts, urea condensate amine salts, and imidazoline salts; and quaternary ammonium salt-type cationic surfactants, such as tetraalkylammonium salts, trialkylbenzyl ammonium salts, quaternary ammonium organic acid salts, fatty acid amide-type quaternary ammonium salts, and alkylpyridinium salts.

Examples of zwitterionic surfactants may include: amino acid-type zwitterionic surfactants, such as alkylglutamic acids, alkyl-β-alanines, and salts thereof; and betaine-type zwitterionic surfactants, such as alkylbetaines.

Examples of anionic surfactants may include: salts of saturated or unsaturated fatty acids having 8 to 22 carbon atoms, such as caprylic acid, capric acid, lauric acid, myristic acid, palmitic acid, stearic acid, oleic acid, linoleic acid, linolenic acid, arachidic acid, behenic acid, and erucic acid, and metals, such as Li, Na, Mg, K, Ca, Ba, and Zn; carboxylate salts, such as polyoxyethylene alkyl ether carboxylate salts and alkyl hydroxy ether carboxylate salts; alkyl sulfate salts, such as higher alcohol sulfate salts (R—O—SO₃M); alkyl ether sulfate salts, such as polyoxyethylene alkyl ether sulfate salts (R—O—(CH₂CH₂O)ₙ—SO₃M); and sulfonate salts, such as alkyl sulfonate salts (R—SO₃M), alkylbenzene sulfonate salts (R-Ph-SO₃M), alkylnaphthalene sulfonate salts (R—Np—SO₃M), olefin sulfonate salts (R—CH═CH—(CH₂)ₙ—SO₃M and R—CH(—OH)(CH₂)ₙ—SO₃M), alkylsulfosuccinate salts (R—OOC—CH₂—CH(—SO₃M)-COOM), dialkylsulfosuccinate salts (R—OOC—CH₂—CH(—SO₃M)-COO—R), α-sulfo fatty acid esters (R—CH(—SO₃M)-COO—CH₃), acylisethionate salts (R—CO—O—(CH₂CH₂)—SO₃M), N-alkyl-N-acylaminoalkyl sulfonate salts such as acyltaurate salts (R—CO—NH—(CH₂)₂—SO₃M) and acylalkyltaurate salts (R—CO—N(—R′)—(CH₂)₂—SO₃M), and condensation products of β-naphthalenesulfonic acid and formalin (M-O₃S-Np-(CH₂—Np(-SO₃M))ₙ—H). The surfactant may be used singly, or two or more types may be used in combination.

In the aforementioned sulfate salts and sulfonate salts, R represents a linear or branched-chain alkyl group containing preferably 8 or more carbon atoms, more preferably 10 or more carbon atoms, even more preferably 12 or more carbon atoms, and preferably 22 or fewer carbon atoms, more preferably 20 or fewer carbon atoms, even more preferably 18 or fewer carbon atoms.

R′ represents a linear or branched-chain alkyl group containing preferably 5 or fewer carbon atoms.

Ph represents a phenyl group that may be substituted.

Np represents a naphthyl group that may be substituted. M represents a monovalent cation, and is preferably a metal ion and more preferably a sodium ion.

Further, n represents a number that is preferably 6 or greater, more preferably 8 or greater, even more preferably 10 or greater, and preferably 24 or less, more preferably 22 or less, even more preferably 20 or less.

As regards the aforementioned sulfate salts and sulfonate salts, one type may be used singly, or two or more types may be used in combination as a mixture.

In cases where an ionic surfactant is to be contained in the single fiber, it is preferable to use an anionic surfactant, more preferably a sulfonate salt, among the aforementioned ionic surfactants. By including such a surfactant, it is possible to efficiently manufacture single fibers with small diameters and nonwoven structures with predetermined densities.

In the cleaning member of the present invention, the nonwoven structure may include constituent components other than the materials constituting the single fibers, so long as the effects of the present invention can be attained. Examples of other constituent components may include polyurethane, polyvinyl acetate, cellulose, or derivatives thereof.

The other constituent components may be included, for example, in the form of fibers constituting the nonwoven structure, or in the form of a layer that is stacked on one surface of the nonwoven structure.

In such cases, the smaller the content of the other constituent components, the more preferable, and the content thereof with respect to 100 parts by mass of all constituent components of the single fiber is preferably 0.5 parts by mass or greater, more preferably 1 part by mass or greater, and preferably 95 parts by mass or less, more preferably 90 parts by mass or less.

Further, in the cleaning member of the present invention, additives may be blended to the single fiber so long as they do not impair the effects of the present invention.

Examples of additives may include antioxidants, light stabilizers, UV absorbers, slip additives, antistatic agents, and metal deactivators.

Examples of antioxidants may include phenol-based antioxidants, phosphite-based antioxidants, and thio-based antioxidants.

Examples of light stabilizers and UV absorbers may include hindered amines, nickel complex compounds, benzotriazoles, and benzophenones. Examples of slip additives may include higher fatty acid amides, such as stearamide.

Examples of antistatic agents may include partial esters of fatty acids, such as glycerin fatty acid monoesters. Examples of metal deactivators may include phosphones, epoxies, triazoles, hydrazides, and oxamides.

In cases where the single fiber further contains an additive, the content of the additive, with respect to 100 parts by mass of all constituent components of the single fiber, is preferably 0.01 parts by mass or greater, more preferably 0.05 parts by mass or greater, and preferably 10 parts by mass or less, more preferably 1 part by mass or less.

From the viewpoint of improving the efficiency of cleaning particulates from an object being cleaned, it is preferable to impregnate the nonwoven structure constituting the cleaning member with a cleaning liquid, depending on the purpose of cleaning.

Water alone may be used as the cleaning liquid. Other examples may include dispersion liquids including water and cleaning agents such as surfactants, bactericides, perfumes, fragrances, deodorants, pH adjusters, organic solvents such as alcohols, polishing particles, etc.

As the cleaning liquid for impregnation, it is possible to use a chemical solution or a polishing solution typically used for polishing electronic components such as substrates.

The above is a description on the cleaning member. Below, a method for manufacturing a cleaning member will be described.

The following method is roughly divided into two steps including: a spinning step of discharging a solution or a melt of an electrospinning composition, containing a material for a single fiber, into an electric field and spinning the solution or the melt by electrospinning, and thereby forming a deposit of the single fiber; and a pressing step of pressing the deposit, and thereby forming a nonwoven structure having a predetermined density.

The following describes, as a preferred embodiment of the manufacturing method of the present invention, an example of electrospinning employing a resin-containing melt.

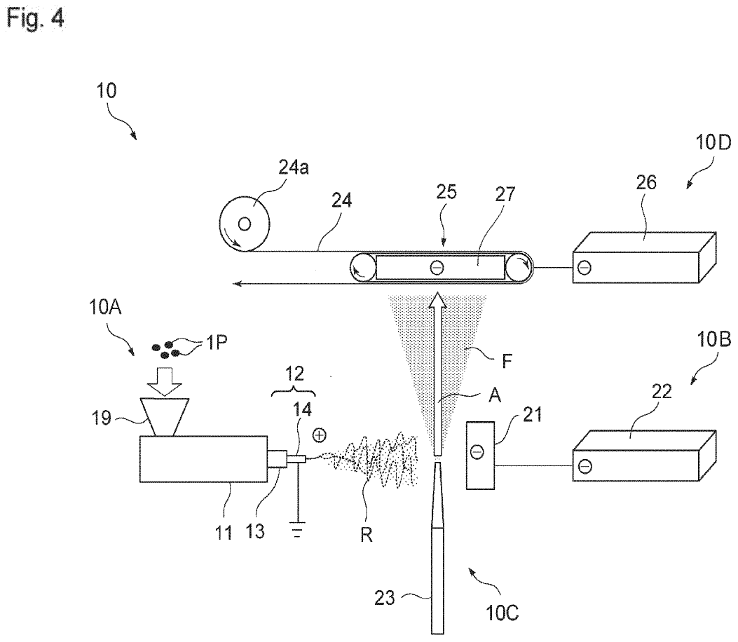

In cases of performing electrospinning by using a melt of an electrospinning composition, the method can be executed suitably by a manufacturing device 10 as illustrated in FIG. 4, for example.

The manufacturing device 10 illustrated in FIG. 4 is roughly divided into a composition supplying unit 10A, an electrode unit 10B, a fluid jetting unit 10C, and a collecting unit 10D.

The manufacturing device 10 includes a composition supplying unit 10A including a housing 11, a discharging nozzle 12, and a hopper 19 to which an electrospinning composition 1P is supplied. In the housing 11, the electrospinning composition 1P supplied from the hopper 19 can be heated and melted in the housing 11 to thereby obtain a melt R of the electrospinning composition. The melt R can be supplied toward the direction of the later-described discharging nozzle 12 by a screw (not illustrated) provided in the housing 11.

The discharging nozzle 12 is a member for discharging the melt R into an electric field, and includes a nozzle base 13 and a discharging nozzle tip-end portion 14. The discharging nozzle 12 is made from an electroconductive material such as metal. The nozzle base 13 and the discharging nozzle tip-end portion 14 are electrically insulated by an insulating member (not illustrated). The housing 11, the discharging nozzle 12, and the nozzle base 13 are in communication with one another, such that the melt R in the housing 11 can be discharged from a discharging opening of the discharging nozzle tip-end portion 14. The discharging nozzle tip-end portion 14 is grounded to the earth.

The discharging nozzle tip-end portion 14 is heated by, for example, transmission of heat from a heater (not illustrated) provided to the nozzle base 13 or transmission of heat from the melt R in the housing 11.

Although dependent on the constituent components of the electrospinning composition, the heating temperature of the melt R at the discharging nozzle tip-end portion 14 is preferably 100° C. or higher, more preferably 200° C. or higher, and preferably 450° C. or lower, more preferably 400° C. or lower.

The manufacturing device 10 includes an electrode unit 10B including a charging electrode 21 and a high-voltage generation device 22 connected thereto. The charging electrode 21 is arranged at a position separated from the discharging nozzle tip-end portion 14 by a predetermined distance, and is arranged facing the discharging nozzle tip-end portion 14.

With this configuration, an electric field is generated between the tip-end portion 14 of the discharging nozzle 12 and the charging electrode 21 to which a high voltage is applied by the high-voltage generation device 22, and thereby, the melt R discharged from the discharging nozzle tip-end portion 14 can be electrically charged.

Preferably, the charging electrode 21 may be made from an electroconductive material such as metal, or may be covered by a dielectric.

Although the distance between the discharging nozzle 12 and the charging electrode 21 depends, for example, on the desired fiber thickness (diameter) or collectability on a later-described collecting electrode 27, the distance is preferably 10 mm or greater, and preferably 150 mm or less. Setting the distance between the discharging nozzle 12 and the charging electrode 21 within this range suppresses occurrence of sparks and corona discharge between the discharging nozzle 12 and the charging electrode 21, thereby inhibiting malfunctioning of the manufacturing device 10.

The manufacturing device 10 further includes a fluid jetting unit 10C. The fluid jetting unit 10C includes a fluid jetting device 23 below a virtual line connecting the composition supplying unit 10A and the electrode unit 10B

The fluid jetting device 23 is provided between the composition supplying unit 10A and the electrode unit 10B.

Between the tip end of the discharging nozzle tip-end portion 14 and the charging electrode 21, an airflow A flows toward a direction intersecting with the direction connecting the tip-end portion and the charging electrode. The airflow A is jetted from the fluid jetting device 23.

The melt R discharged from the discharging nozzle tip-end portion 14 is transported by the airflow A, and can thereby be formed into even finer fiber. With this aim, it is preferable to use air, as a heated fluid, for the airflow A.

Although the temperature of heated air depends on the constituent components of the electrospinning composition, the temperature is preferably 100° C. or higher, more preferably 200° C. or higher, and preferably 500° C. or lower, more preferably 400° C. or lower.

With the same aim, the flow rate of the airflow A at the discharge opening of the fluid jetting device 23 when jetting the airflow A is preferably 50 L/min or greater, more preferably 150 L/min or greater, and preferably 500 L/min or less, more preferably 400 L/min or less.

The manufacturing device 10 further includes a collecting unit 10D.

The collecting unit 10D includes a collecting sheet 24 for collecting fibers F, a transporting conveyor 25 for transporting the fibers F, a high-voltage generation device 26, and a collecting electrode 27.

The collecting unit 10D is located above a virtual line connecting the composition supplying unit 10A and the electrode unit 10B, and is provided at a position opposing the fluid jetting unit 10C. The components of the collecting unit 10D are electrically connected each other.

The collecting sheet 24 is paid out from an original textile roll 24a and is transported by the transporting conveyor 25.

The collecting electrode 27 for collecting electrospun fibers is arranged inside the transporting conveyor 25. The collecting electrode 27 is connected to the high-voltage generation device 26. The high-voltage generation device 26 applies a high voltage to the collecting electrode 27.

Application of high voltage to the collecting electrode 27 causes the fibers F to be drawn toward the transporting conveyor 25, which is negatively charged, and thereby be deposited on the surface of the collecting sheet 24. The collecting electrode 27 may be grounded to the earth, instead of the high-voltage generation device 26.

The above is a description on the manufacturing device 10 illustrated in FIG. 4. Below, a method for manufacturing fibers according to the present invention using the manufacturing device 10 will be described.

First, the hopper 19 is filled with the electrospinning composition 1P, and the electrospinning composition is heated and molten inside the housing 11. The melt R is extruded toward the discharging nozzle 12, to supply the melt R to the discharge opening of the discharging nozzle tip-end portion 14.

The electrospinning composition 1P contains thermoplastic resin, which is a material resin of the intended single fiber, and an ionic surfactant and an additive as necessary. A mixture thereof may be used.

The method for manufacturing the electrospinning composition 1P is not particularly limited. For example, a masterbatch may be produced by mixing the materials in advance; alternatively, each of the materials may be supplied separately to the manufacturing device 10, and the materials may be kneaded while being heated and molten in the device to produce the electrospinning composition.

Next, the melt R is discharged from the discharging nozzle tip-end portion 14 to the electric field, to spin the melt by electrospinning (spinning step). The electric field can be generated, for example, by grounding the tip-end portion 14 of the discharging nozzle 12 and applying a voltage by connecting the charging electrode 21 to the high-voltage generation device 22. The charged melt R is made into an ultrafine fiber by being repeatedly drawn by gravitation and self-repellant force by the melt R's own charge, and is attracted toward the charging electrode 21 by electric attraction.

From the viewpoint of achieving both efficiency of drawing and elongating the melt R and efficiency of manufacturing the fiber, it is preferable that the discharge amount of the molten electrospinning composition is preferably 1 g/min or greater, more preferably 2 g/min or greater, and preferably 20 g/min or less, more preferably 5 g/min or less.

From the viewpoint of facilitating drawing of the melt R at the time of electrospinning and thereby manufacturing a fiber with an even finer diameter, it is preferable to set the melt flow rate (MFR) of the molten electrospinning composition at the discharge opening of the discharging nozzle tip-end portion 14 to 10 g/min or greater, more preferably 100 g/min or greater.

The melt flow rate (MFR) is measured according to JIS K 7210. For example, in cases of using polypropylene resin as a material resin, the melt flow rate is measured at 230° C. under a load of 2.16 kg using an 8-mm long die with a hole diameter of 2.095 mm.

Then, by blowing the airflow A from the fluid jetting device 23 toward the melt R, the melt R discharged from the discharging nozzle tip-end portion 14 is further drawn, and is transported while producing an ultrafine fiber. The melt R discharged from the discharging nozzle tip-end portion 14 is transported by the airflow A before reaching the charging electrode 21, and its flight direction is thus changed; thus, the melt R is drawn/elongated and made ultrafine and is then solidified, to thereby produce a fiber F. The fiber F produced from the melt R is transported by the airflow A and is attracted by electric attraction generated at the collecting electrode 27, and is thus deposited on the surface of the collecting sheet 24 facing the fluid jetting device 23.

The voltage applied between the discharging nozzle 12 and the charging electrode 21 or the collecting electrode 27 is preferably −100 kV or greater, more preferably −80 kV or greater, and preferably −5 kV or less, more preferably −10 kV or less.

Setting the application voltage within this range allows the melt R to be charged satisfactorily, thereby further improving the efficiency of producing fibers with fine diameters. Also, sparks and corona discharge are less likely to occur between the discharging nozzle 12 and the charging electrode 21 or the collecting electrode 27, thus suppressing malfunctioning of the device.

The fiber manufactured in this way is thought to be single piece of fiber continuous from the discharging nozzle 12 to the collecting sheet 24 i.e., a single fiber. Depending on the manufacturing conditions or surrounding environment, the fiber may get cut temporarily; it is thought, however, that the cut fibers will be reconnected immediately, thus forming an ultrafine fiber constituted by a single piece of fiber that is continuous from the discharging nozzle 12 to the collecting sheet 24. The single fiber is deposited on the collecting sheet 24, thereby forming a deposit of the single fiber on the collecting sheet 24.

The single fiber and the deposit thereof manufactured according to the aforementioned steps are obtained by spinning the aforementioned electrospinning composition as the material. Melt electrospinning causes substantially no change in quality/property of the composition, so the makeup of the electrospinning composition, i.e. the material, is substantially identical to the makeup of the single fiber, i.e. the product.

In cases of performing electrospinning using a solution of an electrospinning composition, it is possible to perform fiber spinning by using, for example, a manufacturing device disclosed in JP 2012-012715A or JP 2015-52193A, instead of the aforementioned manufacturing device 10.

More specifically, the device may include: a discharging nozzle for discharging a solution of an electrospinning composition; a syringe in communication with the discharging nozzle and capable of supplying the electrospinning composition to the discharging nozzle; and an electroconductive collector (not illustrated) for collecting fibers that have been spun. In this device, spinning can be performed while applying a voltage between the syringe and the electroconductive collector. The syringe contains a solution of the composition. The solution is supplied from the syringe to the discharging nozzle, and the solution is discharged from the discharging nozzle into an electric field, to thereby electrospin ultrafine single fibers containing the material resin and form a deposit of single fibers on the electroconductive collector.

To manufacture a single fiber having a desired fiber diameter and fiber length, the conditions for executing electrospinning can be changed as appropriate. Particularly, a single fiber called a nanofiber, having an extremely fine fiber diameter, can be manufactured.

As described above, the median fiber diameter of the single fiber is preferably from 100 nm to 2000 nm.

The average fiber length of the single fiber is preferably 10 mm or greater, more preferably 50 mm or greater, even more preferably 100 mm or greater. The average fiber length of the single fiber can be found by measuring the length, in the longitudinal direction, of 500 pieces of fibers and finding the arithmetical mean.

Next, the single fiber deposit that has been formed is pressed, to thereby form a nonwoven structure having an apparent density of preferably from 0.05 g/cm³ to 0.60 g/cm³. To provide the nonwoven structure with an apparent density within the aforementioned range, pressing may be performed by controlling the temperature and the pressure to be applied. The pressure to be applied may be changed as appropriate so that the nonwoven structure is made into a desired shape.

In cases where the deposit of the single fiber is to be molded into a compression-molded product as illustrated in FIG. 2, it is possible to obtain a compressed and molded nonwoven structure 2 by, for example, placing the obtained single fiber deposit in a mold having a shape and size corresponding to that of the intended nonwoven structure, and applying pressure to the deposit.

At this time, the pressure applied to the deposit is preferably 10 N/cm² or greater, more preferably 100 N/cm² or greater, and preferably 100000 N/cm² or less, more preferably 50000 N/cm² or less.

The temperature at the time of pressing can be set as appropriate to a temperature not exceeding the melting point or pour point of the material resin of the single fiber. In cases where a plurality of resins is used as material resins, the temperature is set with reference to the resin having the lowest melting point or pour point among the resins being used.

“Pour point” is found as follows. A resin to be measured is formed into a 40-mm-long, 5-mm-wide, 1-mm-thick plate-shaped solid body. The solid body is placed in a viscoelasticity measurement device (e.g., DMA7100 from Hitachi High-Tech Science Corporation). The dynamic viscoelasticity is measured (with frequency during measurement set to 1 Hz and strain amplitude set to 0.025%) while raising the temperature to a temperature region higher than the glass transition point and glass transition region of the resin being measured; the pour point is found as the temperature at the intersection point between the storage modulus-temperature curve and the loss modulus-temperature curve, when transitioning from a state where the storage modulus E′ is higher than the loss modulus E″ to a state where the loss modulus E″ becomes higher than the storage modulus E′.

In cases of obtaining a nonwoven structure 2 by shaping the single fiber deposit into a sheet-like or plate-like shape as illustrated in FIGS. 3(a) to 3(d), a sheet-like or plate-like nonwoven structure can be obtained by, for example, introducing the obtained single fiber deposit between a pair pressing rollers.

The pressure and temperature at the time of pressing can be set to the aforementioned pressure and temperature.

By pressing the nonwoven structure under the aforementioned conditions, the single fibers will not be fusion-bonded together, but instead, the cross-sectional shape of at least one of the single fibers at the contact point between the fibers will be deformed into a shape that is different from the cross-sectional shape of the single fiber at a non-contact point, regardless of the form into which the nonwoven structure is molded.

In cases of further including a support 3 in addition to the nonwoven structure 2 as illustrated in FIGS. 3(a) to 3(d), it is possible to produce a cleaning member 1 including a nonwoven structure 2 and a support 3 by further performing, for example, a step of covering an outer surface of a support with the nonwoven structure 2 having a sheet-like shape, a step of stacking a support and the nonwoven structure having a sheet-like or plate-like shape, or a step of winding the nonwoven structure 2 having a sheet-like shape around an outer surface of a support.

The method for joining the nonwoven structure 2 and the support 3 is not particularly limited, so long as the effects of the present invention can be attained. For example, the nonwoven structure and the support can be joined partially or entirely by using a joining means such as heat sealing, an adhesive, or the like.

In cases where an ionic surfactant is included in the electrospinning composition, it is also preferable to subject at least the nonwoven structure to a heating treatment, from the viewpoint of making the fiber surface exhibit hydrophilicity more effectively and improving the hydrophilicity of the nonwoven structure.

The method for the heating treatment is not particularly limited, so long as it is performed under conditions not causing fusion-bonding of the single fibers, and examples may include: a method of blowing hot air on the fibers; a method of irradiating the fibers with infrared rays; a method of immersing the fibers in a heated liquid such as hot water; a method of passing the fibers between a pair of heated rollers; a method of retaining the fibers in a heated space such as a temperature-controlled oven; and a method of pressing the fibers by sandwiching the fibers between heated metal plates.

These methods may be performed on the spun single fibers or the deposit thereof as-is, or may be performed simultaneously with the molding of the single fibers into a predetermined shape to form a fiber molded product, or may be performed after forming the molded product.

As regards “conditions not causing fusion-bonding of the single fibers,” the heating treatment may be performed, for example, at a temperature not exceeding the melting point or pour point of the material resin of the single fibers, as described above.

The cleaning member including the nonwoven structure manufactured as above can be used singly as a cleaning member, or may be attached to a cleaning tool, such as a wiper, or to a cleaning device, and can be used for cleaning surfaces of objects to be cleaned, including, for example, buildings parts such as floors and wall surfaces, fittings such as cabinets, windowpanes, mirrors, doors and doorknobs, furniture such as rugs, carpets, desks and dining tables, and the skin surface of the body.

The cleaning member may be used in a dry state, or may be used in a state impregnated with a cleaning liquid or chemical liquid.

Particularly, the cleaning member of the present invention can effectively clean/remove particulates, such as abrasive grains, having particle sizes in the order of several ten to several hundred nanometers. Thus, the cleaning member can be suitably used for cleaning surfaces of precision electronic components—e.g., semiconductor substrates, such as silicon wafers, and magnetic recording substrates—that require a high level of smoothness of the surface being cleaned, and it is possible to reduce the frequency of surface defects on such substrates.

The present invention has been described above according to preferred embodiments thereof, but the present invention is not limited to the foregoing embodiments. For example, in the manufacturing device 10 illustrated in FIG. 4, the composition supplying unit 10A and the fluid jetting unit 10C are provided separately, but instead, the fluid jetting unit 10C may be incorporated into the composition supplying unit 10A.

More specifically, as disclosed in JP 2016-204816A, a manufacturing device may include a nozzle for discharging a solution or a melt of an electrospinning composition, an electrode for generating an electric field between it and the nozzle, a high-voltage generation device for applying voltage to the electrode, and a collecting unit for collecting fibers produced from the electrospinning composition, wherein a flow path through which the solution or the melt can pass is formed between a housing and the nozzle, and a fluid jetting path is formed surrounding the flow path.

In this case, a voltage may be applied to the collecting electrode 27 in the collecting unit 10D, instead of the electrode unit 10B, and an electric field may be generated between it and the nozzle, and in this state, the solution or the melt may be directly discharged from the discharging nozzle 12 toward the collecting unit 10D.

The fluid jetting unit 10C according to this configuration will be able to jet an airflow A along the direction in which the discharging nozzle 12 discharges the melt R.

In the manufacturing device 10 illustrated in FIG. 4, the electrode for generating an electric field between the discharging nozzle 12 is provided separately from the composition supplying unit 10A as the charging electrode 21. Instead, the charging electrode 21 may be incorporated into the composition supplying unit 10A.

More specifically, as disclosed in JP 2016-204816A, the charging electrode 21 may be a concave-surface electrode arranged such that its concave curved surface surrounds the discharging nozzle 12, and a voltage may be applied to such an electrode.

In this case, the collecting unit 10D to be arranged opposing the discharging nozzle 12 may include, for example, a suction means such as a suction box that is not electrically connected, instead of including the collecting electrode 27, and the spun fibers F may be sucked by the suction means and deposited on the collecting sheet 24.

In relation to the foregoing embodiments, the present invention further discloses the following cleaning members and methods for manufacturing the same.

{1}

A cleaning member comprising:

a nonwoven structure, whose shape is retained by entanglement between single fibers having a median fiber diameter of from 100 nm to 2000 nm, and which has an apparent density of from 0.05 g/cm³ to 0.60 g/cm³.

{2}

The cleaning member as set forth in clause {1}, wherein:

the nonwoven structure has a porosity of from 30% to 75%; and

in a pore volume distribution wherein cumulative pore volume is differentiated with respect to a logarithm of pore size, the nonwoven structure has a distribution including a top peak within a pore size range of 50 μm or less and including no top peak within a pore size range of above 50 μm.

{3}

The cleaning member as set forth in clause {1} or {2}, wherein the nonwoven structure is a compression-molded product of a deposit formed by entanglement between the single fibers.

{4}

The cleaning member as set forth in any one of clauses {1} to {3}, further comprising a support, wherein the support and the nonwoven structure are arranged in contact with one another.

{5}

The cleaning member as set forth in clause {4}, wherein the nonwoven structure is arranged so as to cover an entire surface of the support.

{6}

The cleaning member as set forth in clause {4}, wherein the nonwoven structure having a sheet-like shape or bulk-like shape is arranged on at least one surface of the support having a plate-like shape.

{7}

The cleaning member as set forth in clause {4}, wherein the nonwoven structure having a sheet-like shape is arranged on a circumferential surface of the support having a roller-like shape.

{8}

The cleaning member as set forth in any one of clauses {1} to {7}, wherein:

the nonwoven structure has a sheet-like shape; and

permeation time of a water droplet to permeate into the nonwoven structure is 1 minute or less.

{9}

The cleaning member as set forth in any one of clauses {1} to {8}, wherein:

the nonwoven structure has a sheet-like shape; and

permeation time of a water droplet to permeate into the nonwoven structure is preferably 1 minute or less, more preferably 40 seconds or less, even more preferably 20 seconds or less.

{10}

The cleaning member as set forth in any one of clauses {1} to {9}, wherein the single fiber is an electrospun fiber.

{11}

The cleaning member as set forth in any one of clauses {1} to {10}, wherein:

the single fiber contains a thermoplastic resin; and

the thermoplastic resin is at least one type selected from the group consisting of polyolefin resins such as polyethylene, polypropylene, ethylene-α-olefin copolymer and ethylene-propylene copolymer, polyester resins such as polyethylene terephthalate, polyamide resins such as polyamide 6 and polyamide 66, vinyl resins such as polyvinyl chloride and polystyrene, and acrylic resins such as polyacrylate and polymethyl methacrylate.

{12}

The cleaning member as set forth in clause {11}, wherein a content of the thermoplastic resin, with respect to 100 parts by mass of all constituent components of the single fiber, is preferably 70 parts by mass or greater, more preferably 75 parts by mass or greater, even more preferably 80 parts by mass or greater, and preferably 98 parts by mass or less, more preferably 97 parts by mass or less, even more preferably 90 parts by mass or less.

{13}

The cleaning member as set forth in any one of clauses {1} to {12}, wherein the single fiber contains an ionic surfactant.

{14}

The cleaning member as set forth in clause {13}, wherein a content of the ionic surfactant, with respect to 100 parts by mass of all constituent components of the single fiber, is preferably 2 parts by mass or greater, more preferably 4 parts by mass or greater, even more preferably 5 parts by mass or greater, and preferably 10 parts by mass or less, more preferably 8 parts by mass or less, even more preferably 6 parts by mass or less.

{15}

The cleaning member as set forth in any one of clauses {1} to {14}, wherein the nonwoven structure has an apparent density of preferably 0.05 g/cm³ or greater, more preferably 0.10 g/cm³ or greater, even more preferably 0.20 g/cm³ or greater, and preferably 0.60 g/cm³ or less, more preferably 0.55 g/cm³ or less, even more preferably 0.50 g/cm³ or less.

{16}

The cleaning member as set forth in any one of clauses {1} to {15}, wherein the nonwoven structure has a porosity of preferably 30% or greater, more preferably 40% or greater, even more preferably 50% or greater, and preferably 75% or less, more preferably 70% or less, even more preferably 65% or less.

{17}

The cleaning member as set forth in any one of clauses {1} to {16}, wherein the nonwoven structure has a cumulative pore volume of preferably 0.8 mL/g or greater, more preferably 1.0 mL/g or greater, and preferably 20 mL/g or less, more preferably 10 mL/g or less.

{18}

A method for manufacturing the cleaning member as set forth in any one of clauses {1} to {17}, the method comprising:

a step of discharging a solution or a melt of an electrospinning composition into an electric field and spinning the solution or the melt by electrospinning, and thereby forming a deposit of a single fiber; and

a step of pressing the deposit, and thereby forming a nonwoven structure having an apparent density of from 0.05 g/cm³ to 0.60 g/cm³.

{19}

The method for manufacturing the cleaning member as set forth in clause {18}, wherein the nonwoven structure is formed as a compression-molded product by applying, to the deposit, a pressure of preferably 10 N/cm² or greater, more preferably 100 N/cm² or greater, and preferably 100000 N/cm² or less, more preferably 50000 N/cm² or less.

{20}

The method for manufacturing the cleaning member as set forth in clause {18}, wherein the nonwoven structure is formed in a sheet-like or plate-like shape by introducing the deposit between a pair of pressing rollers.

{21}

The method for manufacturing the cleaning member as set forth in any one of clauses {18} to {20}, comprising one of

a step of covering an outer surface of a support with the nonwoven structure having a sheet-like shape,

a step of stacking a support and the nonwoven structure having a sheet-like or plate-like shape, or

a step of winding the nonwoven structure having a sheet-like shape around an outer surface of a support,

to thereby form a cleaning member including the nonwoven structure and the support.

{22}

The method for manufacturing the cleaning member as set forth in any one of clauses {18} to {21}, wherein the nonwoven structure is subjected to a heating treatment.

{23}

The method for manufacturing the cleaning member as set forth in any one of clauses {18} to {22}, comprising:

performing spinning by electrospinning using an electrospinning composition containing a resin, and thereby forming a deposit of a single fiber containing the resin;

pressing the deposit, and thereby forming a nonwoven structure having an apparent density of from 0.05 g/cm³ to 0.60 g/cm³; and

subjecting the nonwoven structure to a heating treatment at a temperature not exceeding the resin's melting point or pour point.

### EXAMPLES

The present invention will be described in further detail below according to Examples. The scope of the present invention, however, is not limited to the following Examples.

### Example 1

The manufacturing device 10 illustrated in FIG. 4 was used. Polypropylene resin (PP; MF650Y from PolyMirae Company Ltd.; melting point: 160° C.) as a material resin and sodium alkyl sulfonate (Mersolat H-95 from Bayer AG) as an ionic surfactant were supplied to the housing 11 such that the content of the ionic surfactant was 5 parts by mass with respect to 100 parts by mass in total of the material resin and the ionic surfactant. These materials were kneaded while being heated and molten in the housing 11, to produce a molten-state electrospinning composition. Using this molten-state electrospinning composition, a deposit of single fiber was manufactured by melt electrospinning under the following manufacturing conditions. The median fiber diameter of the obtained single fiber was 900 nm.

Conditions for Manufacturing Single Fiber:
Manufacturing environment: 27° C., 50% RH.
Heating temperature inside housing 11: 220° C.
Discharge amount of melt R: 1 g/min.
Voltage applied to discharging nozzle tip-end portion 14 (made from stainless steel): 0 kV (grounded to earth).
Voltage applied to charging electrode 21 (80×80 mm, 10 mm thick; made from stainless steel): −40 kV.
Distance between discharging nozzle tip-end portion 14 and collecting unit 10D: 600 mm.
Temperature of airflow jetted from fluid jetting device 23: 350° C.
Flow rate of airflow jetted from fluid jetting device 23: 320 L/min.

Next, the obtained single fiber deposit was supplied to a manual pressing machine (Mini test press-10 from Toyo Seiki Seisaku-sho, Ltd.) and pressed under 9400 N/cm² at room temperature (25° C.), to manufacture a sheet-like nonwoven structure whose shape was retained by entanglement between the single fibers. The thickness of the nonwoven structure was 76 μm, and the water droplet permeation time was 45 seconds. The nonwoven structure had an apparent density of 0.4 g/cm³ and porosity of 55%, and had a pore distribution indicating a top peak at the pore size position of 8 μm. This nonwoven structure was arranged so as to cover the entire outer surface of a plate-like support (a substrate-cleaning pad made from polyvinyl acetal; W series from Aion Co., Ltd.), to thereby obtain a cleaning member 1 of the present Example.

### Comparative Example 1

The aforementioned plate-like support was used as-is as a cleaning member. Stated differently, the cleaning member of the present Comparative Example consisted only of the plate-like support, and no nonwoven structure was provided.

### Example 2

A cleaning member constituted by a nonwoven structure consisting of a compression-molded product was manufactured. More specifically, the single fiber deposit (basis weight: 10 g/m²) obtained according to the aforementioned method was filled into a mold having an 18-mm-long, 18-mm-wide, 30-mm-deep rectangular-parallelepiped shape. Next, a pressure of 25 N/cm² was applied to the single fiber deposit with an 18-mm square plunger die at room temperature (25° C.), to thereby manufacture a nonwoven structure compressed and molded into a rectangular-parallelepiped shape. The nonwoven structure had an apparent density of 0.2 g/cm³.

Evaluation of Particulate Cleaning Capability:

The cleaning members of Example 1 and Comparative Example 1 were each attached to a substrate-cleaning device, and particulate cleaning capability was evaluated by counting the number of defects on the surface of a silicon wafer. More specifically, the procedure involved, in the following order: finish-polishing the silicon wafer; cleaning with the cleaning member; and measuring surface defects. Details and conditions of the evaluation procedure are described below.

1. Finish-Polishing:

A finish-polishing liquid having the following makeup and a silicon wafer were used to perform finish-polishing of the silicon wafer under the following polishing conditions. The silicon wafer was subjected to rough polishing using a commercially available polishing liquid, and was then subjected to finish-polishing under the following finish-polishing conditions. The haze of the silicon wafer after rough polishing was 2 to 3 ppm. “Haze” is a value at the dark field wide oblique incidence channel (DWO) measured using Surfscan SP1-DLS from KLA-Tencor Corporation.

Finish-Polishing Liquid:

A concentrated polishing liquid was obtained by mixing hydroxyethyl cellulose (SE-400 from Daicel Corporation; molecular weight: 250,000), polyethylene glycol (PEG) 6000 (weight-average molecular weight: 6000; Wako 1st Grade from Wako Pure Chemical Industries, Ltd.), ammonia water (Guaranteed Reagent from Kishida Chemical Co., Ltd.), silica particles (PL-3 from Fuso Chemical Co., Ltd.), and ion-exchanged water. Immediately before use, the concentrated polishing liquid was diluted 40-fold with ion-exchanged water, to obtain a finish-polishing liquid. The makeup of the finish-polishing liquid was as follows.
Hydroxyethyl cellulose: 0.01 mass %.
PEG 6000: 0.0008 mass %.
Silica particles: 0.17 mass %.
Ammonia: 0.01 mass %.

Silicon Wafer:

Single-crystal silicon wafer (200-mm-dia. one-surface mirror-polished silicon wafer; conduction type: P; crystal orientation: 100; resistivity: 0.1 Ω·cm or greater to less than 100 Ω·cm).

Finish-Polishing Conditions:
Polishing machine: one-surface 8-inch polishing machine “GRIND-X SPP600s” from Okamoto Machine Tool Works.
Polishing pad: suede pad (from Toray Coatex Co., Ltd.; Asker hardness: 64; thickness: 1.37 mm; nap length: 450 μm; opening diameter: 60 μm).
Silicon wafer polishing pressure: 100 g/cm².
Surface plate rotation speed: 60 rpm.
Polishing time: 5 minutes.
Finish-polishing liquid supplying speed: 150 g/min.
Finish-polishing liquid temperature: 23° C.
Carrier rotation speed: 62 rpm.

2. Cleaning with Cleaning Member:

After finish-polishing, the silicon wafer was subjected to a total of two sets of cleaning, each set including: cleaning with the cleaning member; cleaning with ozone; and cleaning with dilute hydrofluoric acid. Then, the cleaned silicon wafer was rotated at 1,500 rpm for 2 minutes and spin-dried. The conditions for the cleaning were as follows.

In cleaning with the cleaning member, one surface of the wafer was cleaned by moving, while pressing, the cleaning member of the Example or the Comparative Example from the central portion of the silicon wafer toward the outer circumferential portion while jetting ultrapure water at a flow rate of 1 L/min toward the central portion of the silicon wafer rotating at 600 rpm. The cleaning time was set to 1 minute.

In ozone cleaning, ozone water at atmospheric temperature (23° C.) containing 20 ppm of ozone was jetted at a flow rate of 1 L/min for 3 minutes toward the central portion of the silicon wafer rotating at 600 rpm.

In dilute hydrofluoric acid cleaning, an aqueous solution at atmospheric temperature (23° C.) containing 0.5 mass % of ammonium hydrogen fluoride (Guaranteed Reagent from Nacalai Tesque, Inc.) was jetted at a flow rate of 1 L/min for 6 seconds toward the central portion of the silicon wafer rotating at 600 rpm.

3. Measuring Surface Defects:

Surface defects on the cleaned silicon wafer were evaluated by counting the number of particles having particle sizes from 45 nm to 50 nm present on the silicon wafer surface by using Surfscan SP1-DLS from KLA-Tencor Corporation. The evaluation results of surface defects were evaluated based on values at the dark field oblique beam composite channel (DCO) measured using the aforementioned device. The smaller the value, the fewer the surface defects.

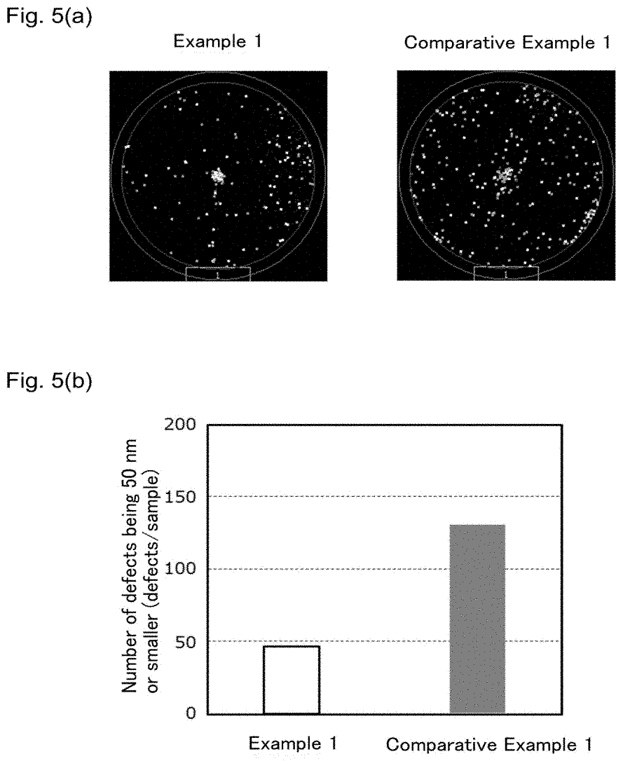

FIGS. 5(a) and 5(b) each show the result of the number of surface defects on the silicon wafer when cleaned using the cleaning member of either Example 1 or Comparative Example 1. FIG. 5(a) shows that the cleaning member has excellent particulate cleaning capability, since there are fewer white dots within the black region inside the circle, which means that there are fewer surface defects.

FIGS. 5(a) and 5(b) show that, with the cleaning member of Example 1, there are fewer particulates remaining on the silicon wafer surface and thus there are fewer surface defects, compared to using the cleaning member of Comparative Example 1. This shows that the cleaning member of the present invention has excellent particulate cleaning capability, and particularly, is suitable for cleaning precision electronic components, such as substrates, which require effective removal of particulates.

### INDUSTRIAL APPLICABILITY

The present invention provides a cleaning member having excellent capability of cleaning/removing particulates adhering to a surface to be cleaned.

1-23. (canceled)

24. A cleaning member comprising:
a nonwoven structure, whose shape is retained by entanglement between single fibers having a median fiber diameter of from 100 nm to 2000 nm, and which has an apparent density of from 0.05 g/cm³ to 0.60 g/cm³.

25. The cleaning member according to claim 24, wherein the single fibers has the median fiber diameter of from 250 nm to 900 nm.

26. The cleaning member according to claim 24, wherein the single fibers are not bonded together.

27. The cleaning member according to claim 24, wherein a cross-sectional shape of at least one of the single fibers at a contact point between the single fibers is deformed into a shape that is different from a cross-sectional shape of the single fiber at a non-contact point.

28. The cleaning member according to claim 27, being used for cleaning a semiconductor substrate after polishing.

29. The cleaning member according to claim 24, wherein:
the nonwoven structure has a porosity of from 30% to 75%; and
in a pore volume distribution wherein cumulative pore volume is differentiated with respect to a logarithm of pore size, the nonwoven structure has a distribution including a top peak within a pore size range of 50 μm or less and including no top peak within a pore size range of above 50 μm.

30. The cleaning member according to claim 24, wherein the nonwoven structure is a compression-molded product of a deposit formed by entanglement between the single fibers.

31. The cleaning member according to claim 24, further comprising a support, wherein the support and the nonwoven structure are arranged in contact with one another.

32. The cleaning member according to claim 24, wherein:
the nonwoven structure has a sheet-like shape; and
permeation time of a water droplet to permeate into the nonwoven structure is 1 minute or less.

33. The cleaning member according to claim 24, wherein:
permeation time of a water droplet to permeate into the nonwoven structure is 0 or more and 45 second or less.

34. The cleaning member according to claim 24, wherein:
the single fiber contains a thermoplastic resin; and
the thermoplastic resin is at least one type selected from the group consisting of polyolefin resins including polyethylene, polypropylene, ethylene-α-olefin copolymer and ethylene-propylene copolymer, polyester resins including polyethylene terephthalate, polyamide resins including polyamide 6 and polyamide 66, vinyl resins including polyvinyl chloride and polystyrene, and acrylic resins including polyacrylate and polymethyl methacrylate.

35. The cleaning member according to claim 34, wherein a content of the thermoplastic resin is from 70 to 98 parts by mass with respect to 100 parts by mass of all constituent components of the single fiber.

36. The cleaning member according to claim 24, wherein the single fiber contains an ionic surfactant.

37. The cleaning member according to claim 36, wherein a content of the ionic surfactant is from 2 to 10 parts by mass with respect to 100 parts by mass of all constituent components of the single fiber.

38. The cleaning member according to claim 24, wherein the nonwoven structure has an apparent density of from 0.10 g/cm³ to 0.55 g/cm³.

39. The cleaning member according to claim 24, wherein the nonwoven structure has an apparent density of from 0.10 g/cm³ to 0.4 g/cm³.

40. The cleaning member according to claim 24, wherein the nonwoven structure has a porosity of from 40% to 70%.

41. The cleaning member according to claim 24, wherein the nonwoven structure has a cumulative pore volume of from 0.8 mL/g to 20 mL/g.

42. A method for manufacturing the cleaning member according to claim 24, the method comprising:
a step of discharging a solution or a melt of an electrospinning composition into an electric field and spinning the solution or the melt by electrospinning, and thereby forming a deposit of a single fiber; and
a step of pressing the deposit, and thereby forming a nonwoven structure having an apparent density of from 0.05 g/cm³ to 0.60 g/cm³.

43. The method for manufacturing the cleaning member according to claim 42, wherein, in the step of forming a deposit of a single fiber, the melt of the electrospinning composition is discharged into an electric field and the melt is spun by electrospinning.
